(19) United States
(12) Patent Application Publication
(10) Pub. No.: US 2008/0213951 A1
(43) Pub. Date: Sep. 4, 2008

(54) Method of fabricating pixel structure

(75) Inventors: Chih-Hung Shih, Hsinchu (TW); Ming-Yuan Huang, Hsinchu (TW); Chih-Chun Yang, Hsinchu (TW); Han-Tu Lin, Hsinchu (TW); Ta-Wen Liao, Hsinchu (TW); Kuo-Lung Fang, Hsinchu (TW); Chia-Chi Tsai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Au Optronics Corporation, Hsinchu (TW)

(21) Appl. No.: 11/953,878

(22) Filed: Dec. 11, 2007

(30) Foreign Application Priority Data
Mar. 3, 2007 (TW) 96107326

(51) Int. Cl. H01L 21/84

(52) U.S. Cl. 438/158; 257/E21.703

(57) ABSTRACT

A method of fabricating a pixel structure including the following procedures is provided. First, a substrate having an active device thereon is provided. A patterned passivation layer is formed on the substrate and the active device, and the patterned passivation layer exposes a portion of the active device. Then, a conductive layer is formed over the patterned passivation layer, and the conductive layer is electrically connected to the active device. A mask exposing a portion of the conductive layer is provided above the conductive layer. A laser is used to irradiate the conductive layer via the mask to remove the portion of the conductive layer exposed by the mask. As a result, the remained portion of the conductive layer constitutes a pixel electrode, and the pixel electrode is electrically connected to the active device. The method simplifies the fabrication process of a pixel structure, and thus reduces the fabrication cost.

### CROSS-REFERENCE TO RELATED APPLICATION

This application claims the priority benefit of Taiwan application serial no. 96107326, filed on Mar. 3, 2007. The entirety of the above-mentioned patent application is hereby incorporated by reference herein and made a part of this specification.

### BACKGROUND OF THE INVENTION

1. Field of the Invention

The present invention relates to a method of fabricating a pixel structure. More particularly, the present invention relates to a method of fabricating a pixel structure which fabricates a pixel electrode through laser ablation.

2. Description of Related Art

Display is a communication interface between human and information, and recently flat panel display is the main developing trend. The flat panel display is mainly classified in the following types: organic electroluminescent display, plasma display panel, thin film transistor liquid crystal display (TFT-LCD), and so on. The TFT-LCD is most widely utilized. Generally, the TFT-LCD is mainly constituted by TFT array substrate, color filter array substrate, and liquid crystal layer. The TFT array substrate includes a plurality of scan lines, a plurality of data lines, and a plurality of pixel structures arranged in an array, and the pixel structures are respectively electrically connected to the corresponding scan lines and data lines.

FIGS. 1A to 1G are flow charts of fabricating a pixel structure in the conventional art. First, referring to FIG. 1A, a substrate 10 is provided, and a gate 20 is formed on the substrate 10 through a first mask process. Then, referring to FIG. 1B, a gate insulation layer 30 is formed on the substrate 10 to cover the gate 20. Next, referring to FIG. 1C, a channel layer 40 located above the gate 20 is formed on the gate insulation layer 30 through a second mask process. Generally, the material of the channel layer 40 is amorphous silicon. After that, referring to FIG. 1D, a source 50 and a drain 60 are formed on a portion of the channel layer 40 and a portion of the gate insulation layer 30 through a third mask process. Seen from FIG. 1D, the source 50 and the drain 60 respectively extend from two sides of the channel layer 40 to above the gate insulation layer 30, and expose a portion of the channel layer 40. Then, referring to FIG. 1E, a passivation layer 70 is formed over the substrate 10 to cover the gate insulation layer 30, the channel layer 40, the source 50, and the drain 60. Next, referring to FIG. 1F, the passivation layer 70 is patterned through a fourth mask process, so as to form a contact hole H in the passivation layer 70. Seen from FIG. 1F, the contact hole H in the passivation layer 70 may expose a portion of the drain 60. Then, referring to FIG. 1G, a pixel electrode 80 is formed on the passivation layer 70 through the fourth mask process. Seen from FIG. 1G, the pixel electrode 80 is electrically connected to the drain 60 via the contact hole H. After the fabrication of the pixel electrode 80, a pixel structure 90 is obtained.

In view of the above, the conventional pixel structure 90 is mainly fabricated through five mask processes. In other words, five masks with different patterns must be employed to fabricate the pixel structure 90. As the fabrication cost of the mask is quite expensive, and each mask process should adopt a mask with a different pattern, if it is impossible to simplify the mask processes, the fabrication cost of the pixel structure 90 cannot be reduced.

In addition, as the size of the TFT-LCD panel is gradually increased, the size of the mask used for fabricating the TFT array substrate is increased accordingly, and the fabrication cost of the mask with a large size will be more expensive, such that the fabrication cost of the pixel structure 90 cannot be effectively reduced.

### SUMMARY OF THE INVENTION

Accordingly, the present invention is directed to provide a method of fabricating a pixel structure, for reducing the fabrication cost.

In order to give a detailed description of the content of the present invention, a method of fabricating a pixel structure is provided. First, a substrate having an active device thereon is provided. Next, a patterned passivation layer is formed on the substrate and the active device, and the patterned passivation layer exposes a portion of the active device. Then, a conductive layer is formed over the patterned passivation layer. After that, a mask is provided above the conductive layer, wherein the mask exposing a portion of the conductive layer. A laser is used to irradiate the conductive layer via the mask to remove the portion of the conductive layer exposed by the mask. As a result, the remained portion of the conductive layer constitutes a pixel electrode connected to the active device.

In the method of fabricating a pixel structure provided by the present invention, the active device on the substrate is, for example, a TFT, and the method of forming the TFT is, for example, first forming a gate on the substrate. Next, a gate insulation layer is formed on the substrate to cover the gate. Then, a channel layer, a source, and a drain are formed on the gate insulation layer above the gate, and the source and the drain are disposed on a portion of the channel layer. More particularly, the above method of forming the gate is, for example, first forming a first metal layer on the substrate, and then patterning the first metal layer to form the gate.

In addition, the channel layer, the source, and the drain are fabricated, for example, through a same mask process. In particular, the method of forming the channel layer, the source, and the drain is, for example, first forming a semiconductor layer on the gate insulation layer, and then forming a second metal layer on the semiconductor layer. Next, a photoresist layer is formed on the second metal layer above the gate, in which the photoresist layer is divided into a first photoresist block and a second photoresist block located on two sides of the first block, and the thickness of the first photoresist block is smaller than the thickness of the second photoresist block. Then, a first etching process is performed on the second metal layer and the semiconductor layer with the photoresist layer as a mask. Afterward, the thickness of the photoresist layer is reduced till the first photoresist block is completely removed. Finally, a second etching process is performed on the second metal layer with the remained second photoresist block as a mask, such that the remained second metal layer constitutes the source and the drain, and the semiconductor layer constitutes the channel layer. In other embodiments, the method of fabricating the channel layer, the source, and the drain further includes forming an ohmic contact layer on a surface of the semiconductor layer after forming the semiconductor layer. Then, the ohmic contact layer not corresponding to the second photoresist block is removed through the first etching process and the second etching process. The above method of reducing the thickness of the photoresist layer includes performing an ashing process.

In the method of fabricating a pixel structure of the present invention, the patterned passivation layer is formed by the following steps. In an embodiment, for example, a dielectric layer is formed on the gate insulation layer and the remained second photoresist block. Then, the remained second photoresist block is removed, such that the dielectric layer on the second photoresist block is together removed to form a patterned passivation layer. The method of removing the remained second photoresist block includes a lift-off process. In another embodiment, for example, the patterned passivation layer is formed by a lithography and etching process. More particularly, after performing the first and the second etching processes and removing the remained second photoresist block, a dielectric layer covering the TFT is first formed on the gate insulation layer, and then, a contact window is formed in the dielectric layer to expose a portion of the drain.

In the method of fabricating a pixel structure of the present invention, the method of forming the conductive layer is, for example, forming an indium tin oxide (ITO) layer or an indium zinc oxide (IZO) layer through sputtering.

In the method of fabricating a pixel structure of the present invention, the energy of the laser for irradiating the conductive layer is, for example, between 10 mJ/cm² and 500 mJ/cm². In addition, the wavelength of the laser is, for example, between 100 nm and 400 nm.

In the present invention, laser ablation is used to fabricate the pixel electrode, which can simplify the fabrication process and reduce the fabrication cost of the mask, as compared with the conventional method. In addition, when the pixel electrode is fabricated, the mask used for laser ablation is relatively small, such that the fabrication cost of the mask used in the process is relatively low.

In order to make the aforementioned and other objectives, features, and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1G are flow charts of fabricating a pixel structure according to the conventional art.

FIG. 2 is a flow chart of fabricating a pixel structure according to the present invention.

FIGS. 3A to 3I are schematic views of the method of fabricating a pixel structure according to a first embodiment of the present invention.

FIG. 4 is a relation diagram of the wavelength of the laser L in use and the absorption of the conductive layer.

FIGS. 5A to 5H are schematic views of the method of fabricating a pixel structure according to a second embodiment of the present invention.

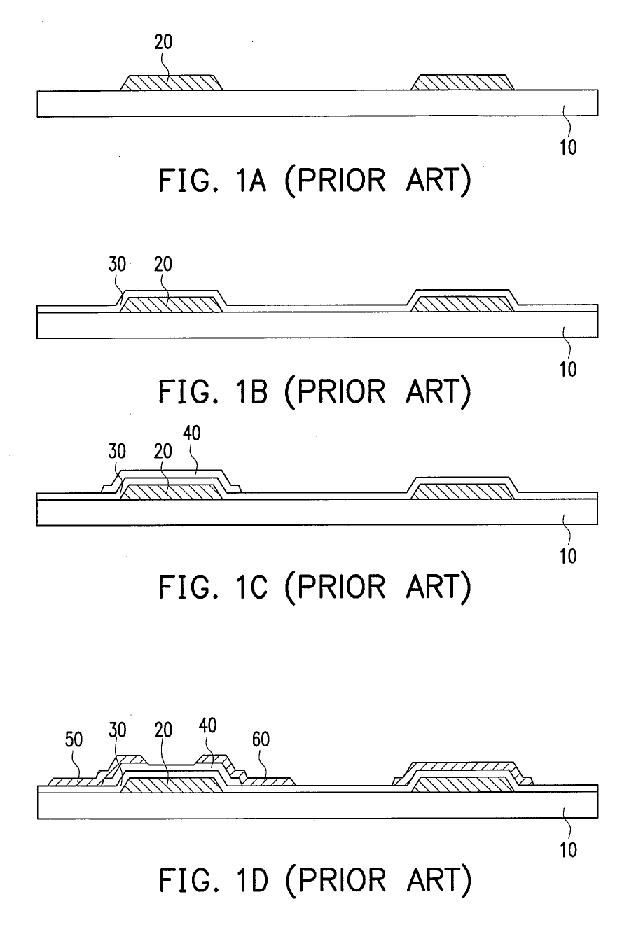

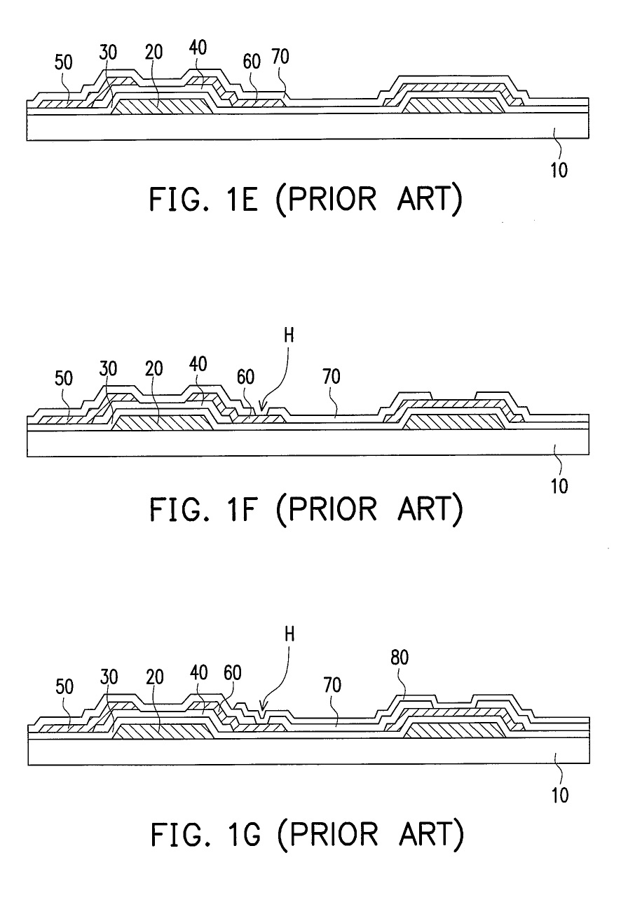

### DESCRIPTION OF EMBODIMENTS

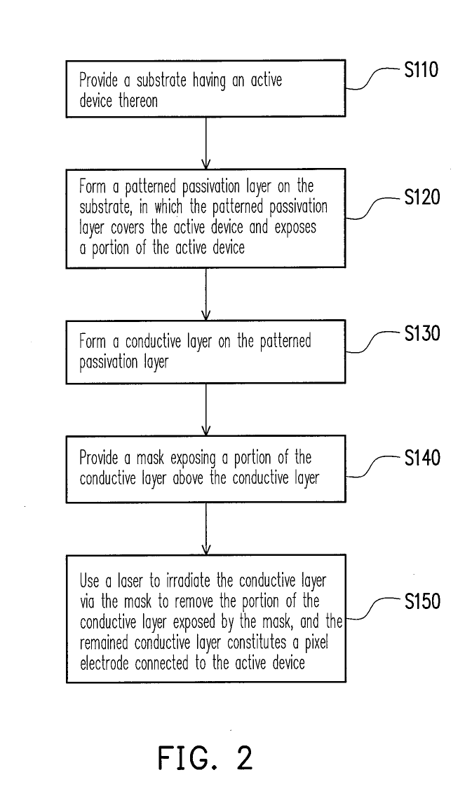

FIG. 2 is a flow chart of fabricating a pixel structure of the present invention. Referring to FIG. 2, the method of fabricating a pixel structure includes the following steps. First, a substrate having an active device thereon is provided (S110). Next, a patterned passivation layer is formed on the substrate, in which the patterned passivation layer covers the active device and exposes a portion of the active device (S120). Then, a conductive layer is formed on the patterned passivation layer (S130), and a mask is provided above the conductive layer, wherein the mask exposes a portion of the conductive layer (S140). A laser is used to irradiate the conductive layer via the mask to remove the portion of the conductive layer exposed by the mask. As a result, the remained portion of the conductive layer constitutes a pixel electrode connected to the active device (S150). In order to make those skilled in the art easily understand the present invention, several embodiments are given below for a detailed description.

### The First Embodiment

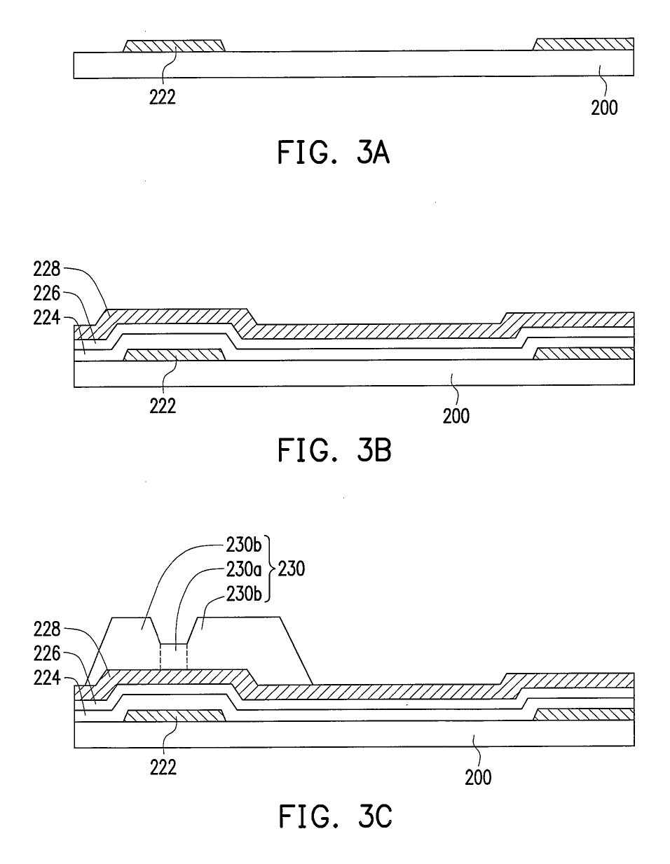

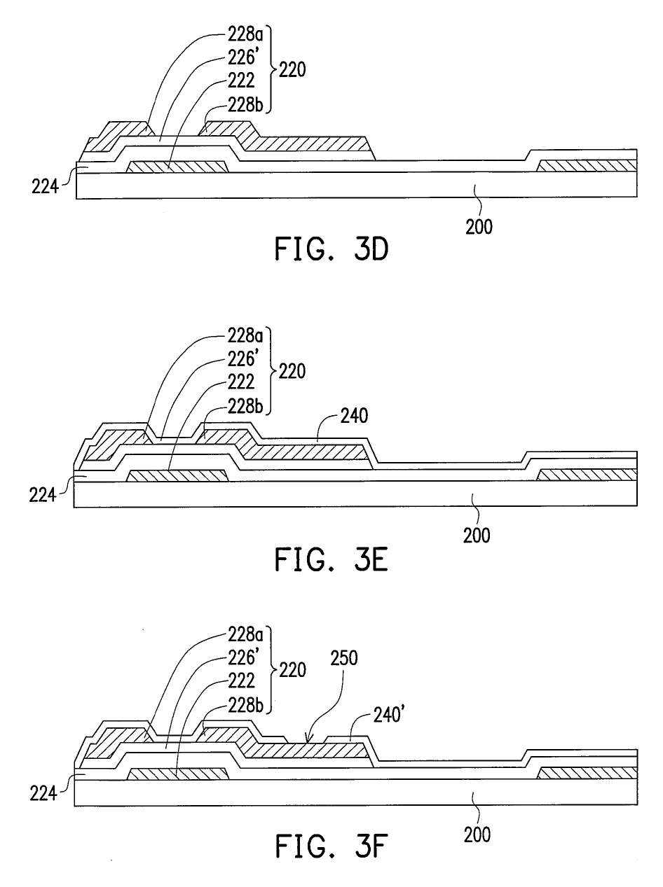

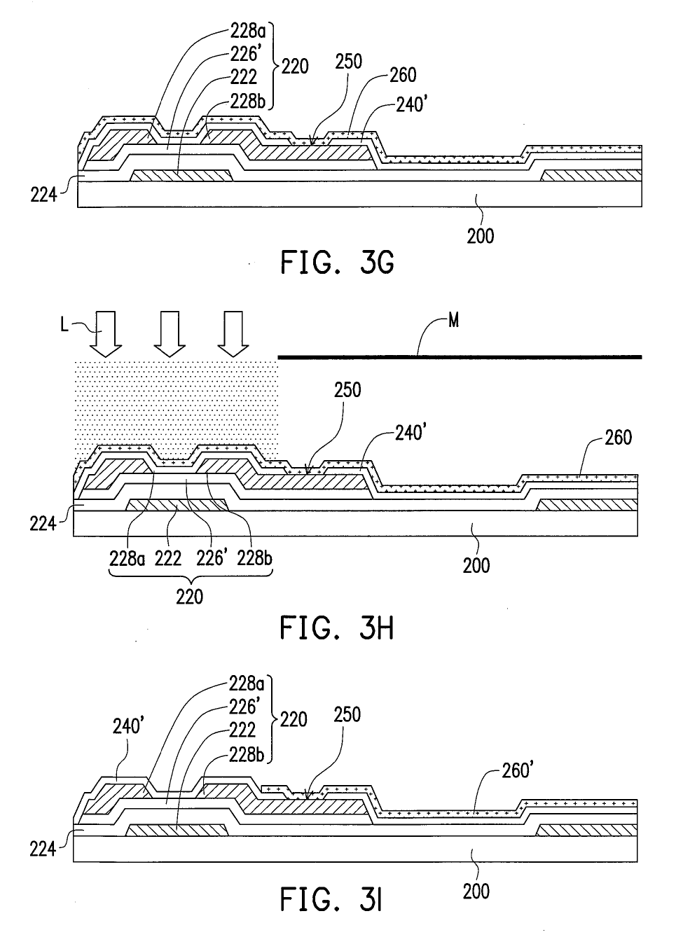

FIGS. 3A to 3I are schematic views of the method of fabricating a pixel structure according to a first embodiment of the present invention. Referring to FIG. 3A, a substrate 200 is first provided, and the material of the substrate 200 is a hard or soft material, for example, glass or plastic. Next, a gate 222 is formed on the substrate 200. In this embodiment, firstly, a first metal layer is formed on the substrate 200, and then the first metal layer is patterned to form the gate 222. The first metal layer is formed by, for example, sputtering, evaporation, or other thin film deposition techniques, and the first metal layer is patterned by, for example, a lithography and etching process.

Afterward, referring to FIG. 3B, a gate insulation layer 224 covering the gate 222 is formed on the substrate 200. In this embodiment, the gate insulation layer 224 is, for example, formed by chemical vapor deposition (CVD) or other suitable thin film deposition techniques, and the material of the gate insulation layer 224 is a dielectric material, such as silicon oxide, silicon nitride, or silicon oxynitride. Next, a semiconductor layer 226 and a second metal layer 228 are sequentially formed on the gate insulation layer 224. In this embodiment, the material of the semiconductor layer 226 is, for example, amorphous silicon or other semiconductor materials, and the material of the second metal layer 228 is, for example, aluminum (Al), molybdenum (Mo), titanium (Ti), neodymium (Nd), nitride of the above such as MoN, TiN, a stacked layer selected from the metals and the nitrides, an alloy selected from the metals, or other applicable conductive materials.

Next, referring to FIG. 3C, after the second metal layer 228 is formed, a photoresist layer 230 is formed on the second metal layer 228 above the gate 222. Seen from FIG. 3C, the photoresist layer 230 is divided into a first photoresist block 230a and a second photoresist block 230b located on two sides of the first block, and the thickness of the first photoresist block 230a is smaller than the thickness of the second photoresist block 230b. Then, a first etching process is performed on the second metal layer 228 and the semiconductor layer 226 with the photoresist layer 230 as a mask. After the first etching process is finished, the second metal layer 228 and the semiconductor layer 226 which are not covered by the photoresist layer 230 are removed. Next, the thickness of the photoresist layer 230 is continuously reduced till the first photoresist block 230a is completely removed. In this embodiment, the thickness of the photoresist layer 230 is reduced by, for example, ashing. After the first photoresist block 230a is completely removed, a second etching process is performed on the second metal layer 228 with the remained second photoresist block 230b as a mask. After the second etching process, the portion of the second metal layer 228 that is not covered by the second photoresist block 230b is removed to simultaneously form a source 228a, a drain 228b, and a channel layer 226′ (as shown in FIG. 3D).

In this embodiment, the first etching process and the second etching process are, for example, wet etching, and in other embodiments, the etching process may also be dry etching. In addition, the photoresist layer 230 is removed by, for example, wet etching.

Referring to FIG. 3D, after the first and the second etching processes are performed and the remained photoresist layer 230 is removed, the fabrication of the active device 220 is almost finished. In this embodiment, the active device 220 is, for example, a TFT, but the type of the active device 220 is not limited in the present invention. Seen from FIGS. 3C and 3D, the channel layer 226′, the source 228a, and the drain 228b in the active device 220 are, for example, formed by a same half-tone mask process or a gray-tone mask process. In other embodiments, before the second metal layer 228 and the photoresist layer 230 (as shown in FIG. 3C) are formed, an ohmic contact layer (not shown) is formed on a surface of the semiconductor layer 226, and then a portion of the ohmic contact layer (not shown) is removed by the first etching process and the second etching process. For example, an N-type doped region is formed on a surface of the semiconductor layer 226 through ion doping, so as to reduce the contact impedance between the semiconductor layer 226 and the second metal layer 228.

Next, referring to FIG. 3E, a dielectric layer 240 covering the active device 220 is formed on the substrate 200. In this embodiment, the material of the dielectric layer 240 is, for example, silicon nitride or silicon oxide, and the method of forming the same is, for example, entirely depositing the dielectric layer 240 on the substrate 200 through physical vapor deposition (PVD) or CVD.

Thereafter, referring to FIG. 3F, the dielectric layer 240 is patterned to form a patterned passivation layer 240′. Seen from FIG. 3F, the patterned passivation layer 240′ has a contact window 250 to expose a portion of the drain 228b of the active device 220. In this embodiment, for example, the contact window 250 is fabricated through lithography and etching.

Continue referring to FIG. 3G, a conductive layer 260 is entirely formed on the patterned passivation layer 240′, and the conductive layer 260 is connected to the drain 228b of the active device 220 via the contact window 250. In this embodiment, the method of forming the conductive layer 260 is, for example, forming an ITO layer or an IZO layer through sputtering.

Then, referring to FIG. 3H, a mask M is provided above the conductive layer 260, and the mask M exposes a portion of the conductive layer 260. Next, a laser L is used to irradiate the conductive layer 260 via the mask M, so as to remove the portion of the conductive layer 260 exposed by the mask M. In this embodiment, the energy of the laser L for removing off a portion of the conductive layer 260 is between 10 mJ/cm² and 500 mJ/cm². In addition, the wavelength of the laser L is, for example, between 100 nm and 400 nm.

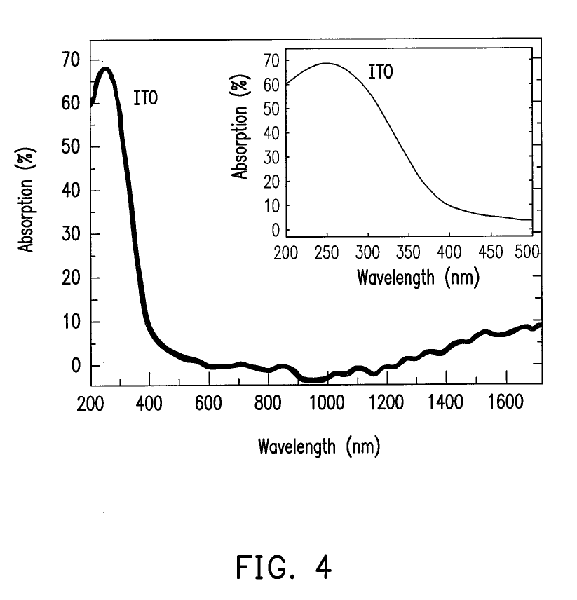

FIG. 4 is a relation diagram of the wavelength of the laser L used in practice and the absorption of the conductive layer 260. In this embodiment, the conductive layer 260 is an ITO layer.

Referring to FIG. 3I, the conductive layer 260 irradiated by the laser L may absorb the energy of the laser L to be lifted off from the surface of the patterned passivation layer 240′, and the conductive layer 260 shielded by the mask M is remained, so as to constitute a pixel electrode 260′. Seen from FIG. 3I, the pixel electrode 260′ is connected to the drain 228b of the active device 220 via the contact window 250 in the patterned passivation layer 240′.

### The Second Embodiment

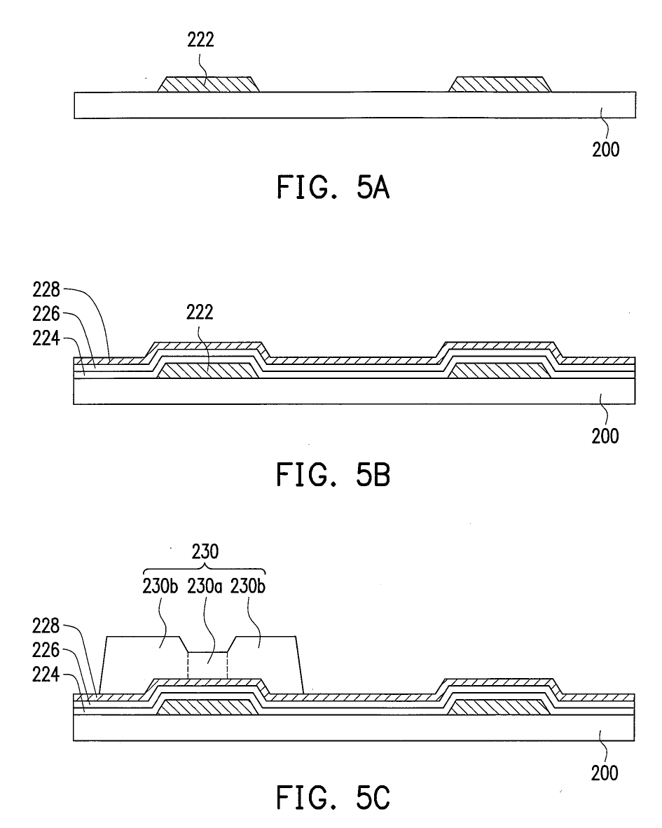

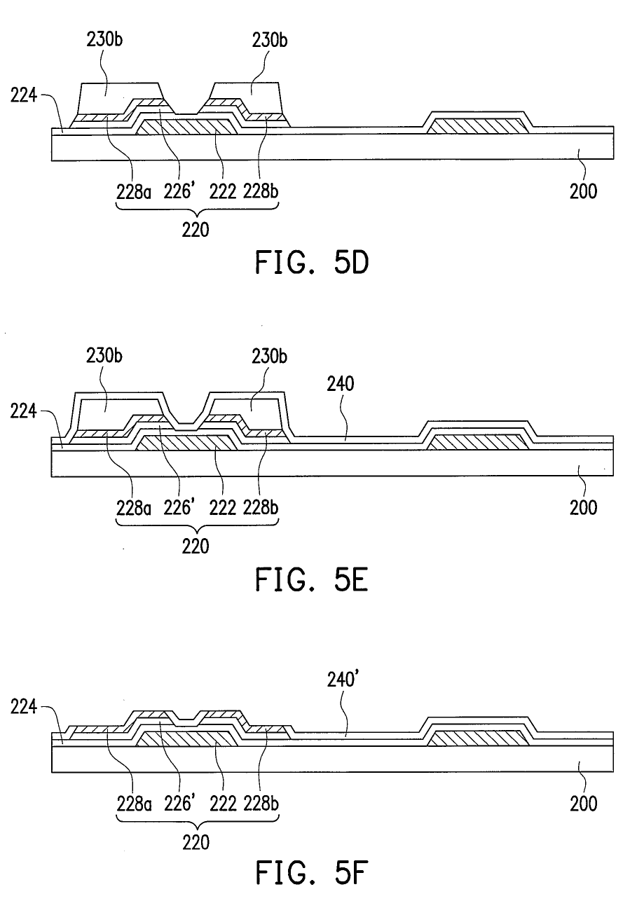

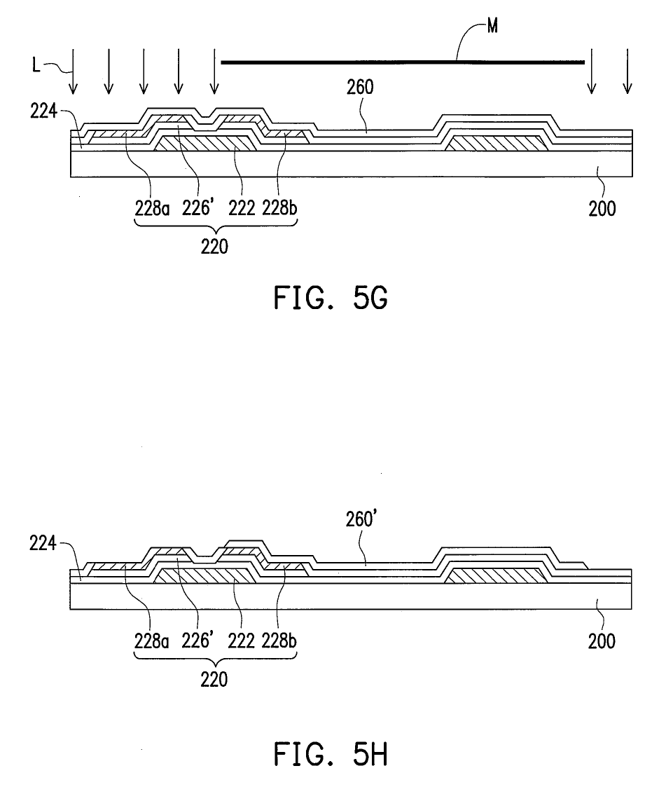

FIGS. 5A to 5H are schematic views of the method of fabricating a pixel structure according to a second embodiment of the present invention. The steps of FIGS. 5A to 5C are similar to those of FIGS. 3A to 3C of the first embodiment, so the description thereof is omitted herein.

Referring to FIG. 5D, after the second etching process is finished, a portion of the second metal layer 228 that is not covered by the second photoresist block 230b and a portion of the semiconductor layer 226 that is not covered by the second metal layer 228 are removed, so as to simultaneously form the source 228a, the drain 228b, and the channel layer 226′.

Then, referring to FIG. 5E, after the source 228a, the drain 228b, and the channel layer 226′ are formed, a dielectric layer 240 is formed to cover the second photoresist block 230b, the channel layer 226′ that is not covered by the second photoresist block 230b, and the gate insulation layer 224 that is not covered by the channel layer 226′.

Afterward, referring to FIG. 5F, the remained second photoresist block 230b is removed, such that the dielectric layer 240 on the second photoresist block 230b is removed together. After the second photoresist block 230b is removed, the dielectric layer 240 is patterned to form a patterned passivation layer 240′, and the source 228a, the drain 228b are exposed out of the patterned passivation layer 240′. In this embodiment, the second photoresist block 230b is removed by, for example, a lift-off process. It should be noted that the photoresist layer 230 adopted in this embodiment can be used to form the source 228a, the drain 228b, the channel layer 226′, and the patterned passivation layer 240′, so as to effectively reduce the fabrication cost.

Continue referring to FIG. 5G, a conductive layer 260 is entirely formed on the patterned passivation layer 240′, and the conductive layer 260 is directly connected to the drain 228b of the active device 220. Then, a mask M is provided above the conductive layer 260. The mask M exposes a portion of the conductive layer 260. After that, a laser L is used to irradiate the conductive layer 260 via the mask M, so as to remove the portion of the conductive layer 260 exposed by the mask M. In this embodiment, the energy of the laser L for lifting off a portion of the conductive layer 260 is between 10 mJ/cm² and 500 mJ/cm². In addition, the wavelength of the laser L is, for example, between 100 m and 400 nm.

Next, referring to FIG. 5H, the conductive layer 260 irradiated by the laser L may absorb the energy of the laser L to be lifted off the surface of the patterned passivation layer 240′, and the conductive layer 260 shielded by the mask M is remained, so as to constitute a pixel electrode 260′. Seen from FIG. 5H, the pixel electrode 260′ is directly connected to the drain 228b of the active device 220.

To sum up, in the present invention, the pixel electrode is formed by laser irradiation, instead of a conventional lithography and etching process, such that the method of fabricating a pixel structure provided by the present invention at least has the following advantages.

1. In the method of fabricating a pixel structure of the present invention, it is not necessary to use a lithography process for fabricating the pixel electrode, thus reducing the fabrication cost of the mask, as compared with the high-precision mask process adopted by the lithography process.

2. As the process of fabricating the pixel structure is simplified, the disadvantages occurred during a redundant mask process for fabricating a pixel structure (such as photoresist coating, soft baking, hard baking, exposing, developing, etching, photoresist stripping) can be avoided.

3. The method of ablating a portion of the pixel electrode with a laser provided by the present invention can be used for pixel fixing, so as to remove the possibly material residue (such as ITO residue) in the fabrication of a pixel structure, thus solving the short circuit problem between the pixel electrodes, and increasing the production yield.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a pixel structure, comprising:
providing a substrate, having an active device formed thereon;
forming a patterned passivation layer on the substrate and the active device, wherein the patterned passivation layer exposes a portion of the active device;
forming a conductive layer on the patterned passivation layer;
providing a mask above the conductive layer, the mask exposing a portion of the conductive layer; and
using a laser to irradiate the conductive layer via the mask to remove the portion of the conductive layer exposed by the mask, such that the remained conductive layer constitutes a pixel electrode connected to the active device.

2. The method of fabricating a pixel structure as claimed in claim 1, wherein the active device is a thin film transistor (TFT).

3. The method of fabricating a pixel structure as claimed in claim 2, wherein the method of forming the TFT comprises:
forming a gate on the substrate;
forming a gate insulation layer on the substrate to cover the gate; and
forming a channel layer, a source, and a drain on the gate insulation layer above the gate, wherein the source and the drain are disposed on a portion of the channel layer.

4. The method of fabricating a pixel structure as claimed in claim 3, wherein the method of forming the gate comprises:
forming a first metal layer on the substrate; and
patterning the first metal layer to form the gate.

5. The method of fabricating a pixel structure as claimed in claim 3, wherein the channel layer, the source, and the drain are formed by a same mask process.

6. The method of fabricating a pixel structure as claimed in claim 3, wherein the method of forming the channel layer, the source, and the drain comprises:
forming a semiconductor layer on the gate insulation layer;
forming a second metal layer on the semiconductor layer;
forming a photoresist layer on the second metal layer above the gate, wherein the photoresist layer is divided into a first photoresist block and a second photoresist block located on two sides of the first block, and the thickness of the first photoresist block is smaller than the thickness of the second photoresist block;
performing a first etching process on the second metal layer and the semiconductor layer with the photoresist layer as a mask;
reducing the thickness of the photoresist layer till the first photoresist block is completely removed; and
performing a second etching process on the second metal layer with the remained second photoresist block as a mask, such that the remained second metal layer constitutes the source and the drain, and the semiconductor layer constitutes the channel layer.

7. The method of fabricating a pixel structure as claimed in claim 6, wherein the method of forming the channel layer, the source, and the drain further comprises:
forming an ohmic contact layer on a surface of the semiconductor layer after forming the semiconductor layer; and
removing the ohmic contact layer not corresponding to the second photoresist block through the first etching process and the second etching process.

8. The method of fabricating a pixel structure as claimed in claim 6, wherein the method of reducing the thickness of the photoresist layer comprises performing an ashing process.

9. The method of fabricating a pixel structure as claimed in claim 1, wherein the method of forming the conductive layer comprises forming an indium tin oxide (ITO) layer or an indium zinc oxide (IZO) layer through sputtering.

10. The method of fabricating a pixel structure as claimed in claim 1, wherein the energy of the laser is between 10 mJ/cm² and 500 mJ/cm².

11. The method of fabricating a pixel structure as claimed in claim 1, wherein the wavelength of the laser is between 100 nm and 400 nm.

12. A method of fabricating a pixel structure, comprising:
providing a substrate;
forming a gate on the substrate;
forming a gate insulation layer on the substrate to cover the gate;
forming a channel layer, a source, and a drain simultaneously on the gate insulation layer above the gate, wherein the source and the drain are disposed on a portion of the channel layer, and the gate, the channel layer, the source, and the drain constitute a TFT;
forming a patterned passivation layer on the gate insulation layer and the TFT;
forming a conductive layer to cover the patterned passivation layer;
providing a mask above the conductive layer, the mask exposing a portion of the conductive layer; and
using a laser to irradiate the conductive layer via the mask to remove the portion of the conductive layer exposed by the mask, such that the remained conductive layer constitutes a pixel electrode connected to the drain.

13. The method of fabricating a pixel structure as claimed in claim 12, wherein the method of forming the gate comprises:
forming a first metal layer on the substrate; and
patterning the first metal layer to form the gate.

14. The method of fabricating a pixel structure as claimed in claim 12, wherein the method of forming the channel layer, the source, and the drain comprises:
forming a semiconductor layer on the gate insulation layer;
forming a second metal layer on the semiconductor layer;
forming a photoresist layer on the second metal layer above the gate, wherein the photoresist layer is divided into a first photoresist block and a second photoresist block located on two sides of the first block, and the thickness of the first photoresist block is smaller than the thickness of the second photoresist block; and
performing a first etching process on the second metal layer and the semiconductor layer with the photoresist layer as a mask;
reducing the thickness of the photoresist layer till the first photoresist block is completely removed; and
performing a second etching process on the second metal layer with the remained second photoresist block as a mask, such that the remained second metal layer constitutes the source and the drain, and the semiconductor layer constitutes the channel layer.

15. The method of fabricating a pixel structure as claimed in claim 14, wherein the method of forming the patterned passivation layer comprises:
forming a dielectric layer on the gate insulation layer and the remained second photoresist block; and
removing the remained second photoresist block, so as to together remove the dielectric layer on the second photoresist block.

16. The method of fabricating a pixel structure as claimed in claim 15, wherein the method of removing the remained second photoresist block comprises a lift-off process.

17. The method of fabricating a pixel structure as claimed in claim 14, wherein the method of forming the channel layer, the source, and the drain further comprises:
forming an ohmic contact layer on a surface of the semiconductor layer after forming the semiconductor layer; and
removing the ohmic contact layer not corresponding to the second photoresist block through the first etching process and the second etching process.

18. The method of fabricating a pixel structure as claimed in claim 14, wherein the method of reducing the thickness of the photoresist layer comprises performing an ashing process.

19. The method of fabricating a pixel structure as claimed in claim 12, wherein the method of forming the patterned passivation layer comprises:
forming a dielectric layer covering the TFT on the gate insulation layer; and
forming a contact window in the dielectric layer to expose a portion of the drain.

20. The method of fabricating a pixel structure as claimed in claim 12, wherein the method of forming the conductive layer comprises forming an ITO layer or an IZO layer through sputtering.

21. The method of fabricating a pixel structure as claimed in claim 12, wherein the energy of the laser is between 10 mJ/cm² and 500 mJ/cm².

22. The method of fabricating a pixel structure as claimed in claim 12, wherein the wavelength of the laser is between 100 nm and 400 nm.
